(19) United States
(12) Patent Application Publication
(10) Pub. No.: US 2015/0279623 A1
(43) Pub. Date: Oct. 1, 2015

(54) COMBINED INDUCTIVE AND CAPACITIVE SOURCES FOR SEMICONDUCTOR PROCESS EQUIPMENT

(71) Applicant: Applied Materials, Inc., Santa Clara, CA (US)

(72) Inventor: Qiwei LIANG, Fremont, CA (US)

(21) Appl. No.: 14/224,951

(22) Filed: Mar. 25, 2014

(51) Int. Cl. H01J 37/32

(52) U.S. Cl. CPC H01J 37/32091; H01J 37/321; H01J 37/3244; H01J 2237/334; H01J 2237/332

(57) ABSTRACT

A chamber for processing a substrate is provided. The chamber includes a chamber body having one or more sidewalls and a bottom with a substrate support disposed inside the chamber body. The chamber also includes a showerhead disposed above the substrate support. The showerhead includes a showerhead faceplate that faces the substrate support and is electrically coupled to a capacitive RF power source. A space between the substrate support and the showerhead faceplate defines a processing volume. The chamber further includes one or more coils disposed outside the processing volume at a vertical location between the substrate support and the showerhead. The one or more coils are electrically coupled to one or more inductive RF power sources.

### BACKGROUND

1. Field

Aspects of the present invention relate generally to creating plasmas in semiconductor processing chambers. More particularly, embodiments of the present invention to an apparatus for improving plasma uniformity in a plasma chamber.

2. Description of the Related Art

Plasmas are partially ionized gases used in a variety of semiconductor applications, such as depositions (e.g., plasma enhanced chemical vapor depositions (PECVD) and high density plasma chemical vapor depositions (HDPCVD)), etchings, selective removal processes, and sputtering processes. External electromagnetic fields are used to create plasmas inside processing chambers in close proximity to the semiconductor substrate being processed. An external electric field can be used to create a capacitively coupled plasma (CCP) by applying a radio frequency (RF) power to one or more electrodes located near the substrate while an external magnetic field can be used to create an inductively coupled plasma (ICP) by applying RF power to one or more inductive coils located near the substrate. Conventional semiconductor processes have typically employed one chamber to create a CCP and another chamber to create an ICP. Broadly speaking, a CCP process creates a low density plasma with high energy ions while an ICP process creates a high density plasma with low energy ions. Due to the different properties of the plasmas created by CCP processes and ICP processes, a gap exists between the process conditions, such as plasma density and operating pressure, typically created by each respective process.

Plasma non-uniformity also remains an issue for CCP and ICP processes. Plasma non-uniformity leads to non-uniformities on the substrate being processed, which is undesirable. In a CCP process, the region of plasma non-uniformity depends on the type and location of the electrodes among other factors. In an ICP process, the region of plasma non-uniformity depends on the type and location of the inductive coils among other factors. Furthermore, the operating conditions for a CCP and an ICP can vary substantially, making it difficult to use a single semiconductor processing chamber for different applications.

Therefore, a need exists for an improved semiconductor processing chamber that reduces plasma non-uniformity and allows for additional process conditions to be explored.

### SUMMARY

In one embodiment, a chamber for processing a substrate is provided. The chamber includes a chamber body having one or more sidewalls and a bottom with a substrate support disposed inside the chamber body. The chamber also includes a showerhead disposed above the substrate support. The showerhead includes a showerhead faceplate electrically coupled to a capacitive RF power source, wherein the showerhead faceplate faces the substrate support. A space between the substrate support and the showerhead faceplate defines a processing volume. The chamber further includes one or more coils disposed outside the processing volume at a vertical location between the substrate support and the showerhead faceplate, wherein the one or more coils are electrically coupled to one or more inductive RF power sources.

In another embodiment, a chamber for processing a substrate is provided. The chamber includes a chamber body having one or more sidewalls and a bottom with a substrate support disposed inside the chamber body. The chamber also includes a showerhead disposed above the substrate support. The showerhead includes a showerhead faceplate electrically coupled to a capacitive RF power source, wherein the showerhead faceplate faces the substrate support. The chamber further includes one or more coils disposed outside of the chamber body at a vertical location between the substrate support and the showerhead, wherein the one or more coils are electrically coupled to one or more inductive RF power sources.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view according to one embodiment of the present invention.

FIG. 2 is a schematic cross sectional view according to another embodiment of the present invention.

FIG. 3A is a schematic cross sectional view of a dual-channel showerhead to be implemented in accordance with another embodiment of the present invention.

FIG. 3B is a schematic cross sectional view of a tri-channel showerhead to be implemented in accordance with another embodiment of the present invention.

FIG. 4 is a schematic cross sectional view according to another embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

A chamber is provided that improves plasma uniformity and is capable of creating plasmas in a wider range of process conditions than previous chambers, allowing multiple process steps to be completed in a single chamber.

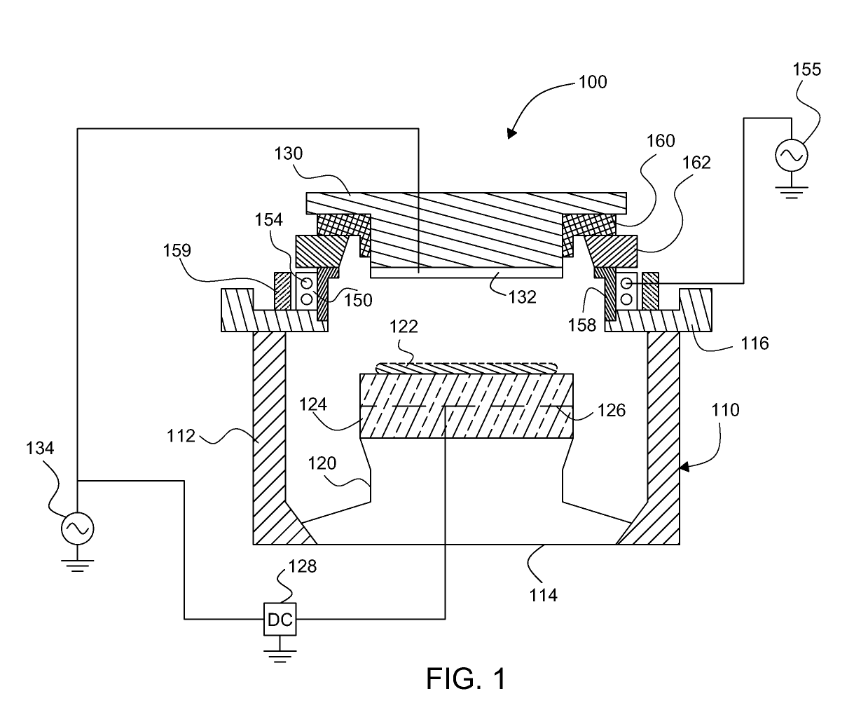

FIG. 1 is a cross sectional view of a chamber 100 according to one embodiment of the present invention. Chamber 100 could be used for processing a substrate 122. The chamber 100 includes a chamber body 110 having sidewalls 112 and a bottom 114. A lid plate 116 is secured to the chamber body 110 on top of the sidewalls 112.

A substrate support 120 is disposed inside the chamber body 110 for supporting substrate 122. Substrate support 120 includes an electrostatic chuck 124 for holding substrate 122 in place during processing. In some embodiments a ceramic heater (not shown) can be used with electrostatic chuck 124 or in place of electrostatic chuck 124. Either or both of the electrostatic chuck 124 or the ceramic heater may be stationary or movable. The substrate support 120 generally includes a plurality of lift pins (not shown) disposed therethrough that are configured to lift the substrate from the substrate support 120 and facilitate exchange of the substrate 122 with a robot (not shown) in a conventional manner.

A showerhead 130 is disposed above substrate support 120 and above lid plate 116. Showerhead 130 is coupled to one or more gas inlet passages (not shown) and includes a showerhead faceplate 132 for dispersing process gases to the interior of chamber 100. The showerhead faceplate 132 faces the substrate support 120, and the space between the top of substrate support 120 and the bottom of showerhead faceplate 132 defines a processing volume.

Showerhead faceplate 132 could be electrically coupled to a capacitive RF power source 134. Capacitive RF power source 134 may generate high frequency power, such as frequency between 1 MHz and 100 MHz, such as 13.56 MHz or 60 MHz. Electrostatic chuck 124 could have an embedded electrode 126 electrically coupled to the capacitive RF power source 134 and a DC biasing power source 128. In some embodiments, a separate capacitive RF power source (not shown) could be coupled to the electrode 126 instead of capacitive RF power source 134. Application of RF power to showerhead faceplate 132 and electrode 126 creates an oscillating electric field inside chamber 100 ionizing process gases supplied to chamber 100 into a plasma. A RF matching network (not shown) could be placed between capacitive RF power source 134 and showerhead faceplate 132. Electrode 126 could also be coupled to DC biasing power source 128 to create a DC bias, which can be used to electrostatically secure substrate 122 to electrostatic chuck 124. In some embodiments, DC biasing power source 128 is coupled to capacitive RF power source 134, and in other embodiments DC power source could be coupled to another capacitive RF power source (not shown) or to no other power source. Embodiments described herein could also use a bipolar chuck, a tripolar chuck, an interdigitated chuck, a zoned chuck and the like.

An inductive coil, coil 154, could be mounted on top of lid plate 116 in a coil housing 150. Coil 154 could be a flat coil or a cylindrical coil. Coil 154 taking a flat or cylindrical shape could form one or more rings around the chamber body 110 surrounding the processing volume. One or more coils (e.g., coil 154) could be disposed outside the processing volume or outside the chamber body 110 at a vertical location between the substrate support 120 and the showerhead faceplate 132. If coil 154 has multiple rings, then the rings could have different vertical locations, different diameters, or a combination of both. In FIG. 1, coil 154 is shown as a cylindrical coil with two rings disposed at different vertical locations.

Coil 154 could be electrically coupled to inductive RF power source 155 at a frequency between 500 kHz and 100 MHz, such as 2 MHz or 13.56 MHz with between 100 W to 100 kW of power, such as between 1 kW to 10 kW of power. If one or more coils (e.g., coil 154) are used, then the one or more coils could be electrically coupled to on ore more inductive RF power sources (e.g., inductive RF power source 155). A RF matching network (not shown) could be placed between inductive RF power source 155 and coil 154. Coil insulator 158 electrically insulates coil 154 from the interior of chamber 100. When inductive RF power source 155 is powered, magnetic fields are directed from coil 154 to the interior of chamber 100 in order to ionize process gases inside chamber 100.

A magnetic field concentrator 159 could be used concentrate the magnetic fields to desired areas within chamber 100. The magnetic field concentrator 159 is typically formed from a material having relatively high magnetic permeability, such as ferrite. The magnetic field concentrator 159 works to reduce the extent of the magnetic field through the magnetic field concentrator 159 and increase the extent of the magnetic field away from the magnetic field concentrator 159, such as in the chamber 100. The magnetic field concentrator 159 may be disposed around the coil 154, such as radially outward of the coil 154, to increase the extent of the magnetic field into the chamber 100.

Showerhead 130 is mounted on top of showerhead insulator 160 and a ground spacer 162 to electrically isolate showerhead 130 from the chamber body 110 and coil 154. A clamp (not shown) or other fastening means could be used to secure showerhead 130 in place.

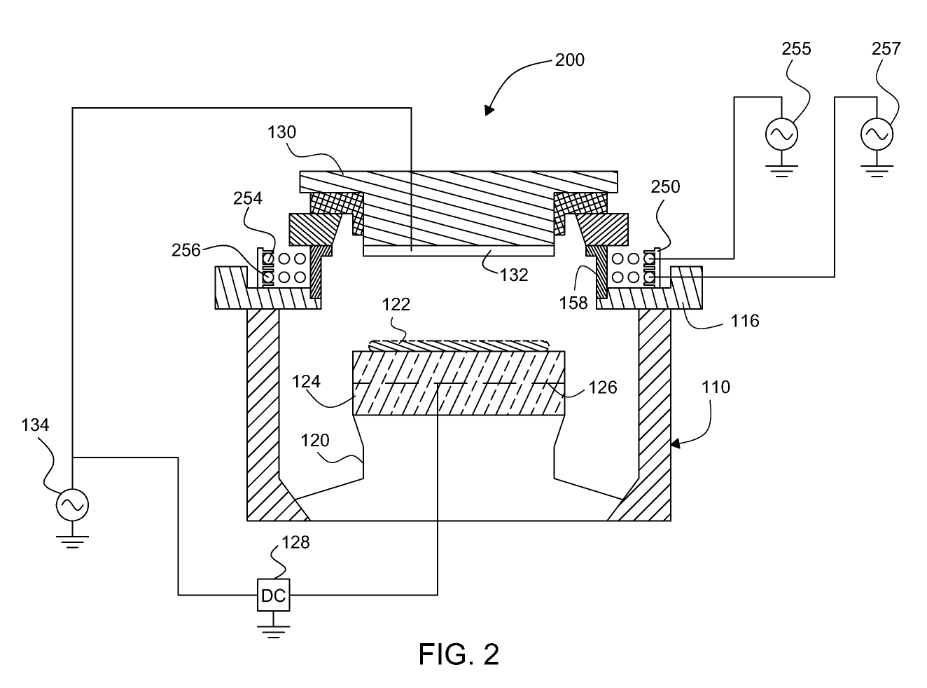

FIG. 2 is a cross sectional view of a chamber 200 according to another embodiment of the present invention. In this embodiment, chamber 200 utilizes a coil clamp 250 to mount two coils to the chamber 200. The two coils include an upper coil 254 disposed above a lower coil 256 on top of lid plate 116. The upper coil 254 and the lower coil 256 could surround the processing volume or the chamber body 110. Use of more than one inductive coil is another method for controlling plasma density. The positions of upper coil 254 and a lower coil 256 could each be adjustable. Coil clamp 250 can be used to adjust the position of the upper coil 254 and the lower coil 256. Although clamp 250 is shown as the means for adjusting the position of upper coil 254 and lower coil 256, other conventional means could be used, such as a mounting plate with adjustable brackets. Automatic means, such as one or more linear actuators, could also be used for adjusting the positions of the upper coil 254 and lower coil 256 easing position changes during and between processing.

Upper coil 254 and lower coil 256 could be flat coils or cylindrical coils. Each coil 254, 256 taking a flat or cylindrical shape could form one or more rings around the chamber body 110 surrounding the processing volume. If each coil 254, 256 has multiple rings, then the rings could have different vertical locations, different diameters, or a combination of both. In FIG. 2, upper coil 254 and lower coil 256 are each shown as a cylindrical coil having three rings of varying diameters.

Upper coil 254 and lower coil 256 could each be electrically coupled to separate inductive RF power sources. Upper coil 254 could be electrically coupled to inductive RF power source 255, and lower coil 256 could be electrically coupled to inductive RF power source 257. Alternatively, upper coil 254 and lower coil 256 could be electrically coupled to the same inductive RF power source. In some embodiments, three or more coils could be used, and the coils could each be electrically coupled to a separate RF power source, or some or all of the coils could share the same RF power source. One or more magnetic field concentrators (e.g., magnetic field concentrator 159) could be disposed proximate upper coil 254 and lower coil 256 and could also be used in any embodiments with two or more coils.

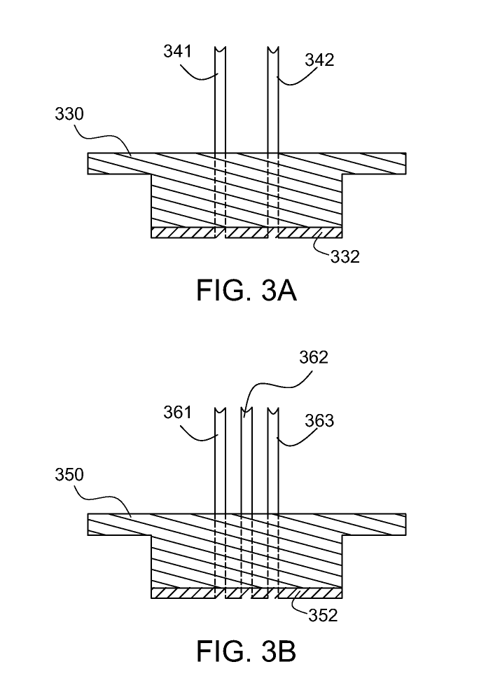

FIG. 3A is a cross sectional view of a dual-channel showerhead 330 to be implemented in accordance with another embodiment of the present invention. Referring to FIGS. 1, 2, and 3A, in some embodiments the showerhead 130 could be replaced with a dual-channel showerhead 330. Dual-channel showerhead 330 includes a faceplate 332, a process gas 1 inlet line 341 and a process gas 2 inlet line 342. The process gas inlet lines 341-342 are routed through dual-channel showerhead 330 to separate apertures (not shown) in faceplate 332 to maintain separation of the process gases until delivery to the interior of a processing chamber, such as chamber 100. This separation prevents any undesired interactions between the process gases before delivery to the chamber interior and can improve plasma uniformity.

FIG. 3B is a cross sectional view of a tri-channel showerhead 350 to be implemented in accordance with another embodiment of the present invention. Referring to FIGS. 1, 2, and 3B, in some embodiments the showerhead 130 could be replaced with a tri-channel showerhead 350. Tri-channel showerhead 350 includes a faceplate 352, a process gas 1 inlet line 361, a process gas 2 inlet line 362, and a process gas 3 inlet line 363. The process gas inlet lines 361-363 are routed through tri-channel showerhead 350 to separate apertures (not shown) in faceplate 352 to maintain separation of the process gases until delivery to the interior of a processing chamber, such as chamber 100. This separation prevents any undesired interactions between the process gases before delivery to the chamber interior and can improve plasma uniformity.

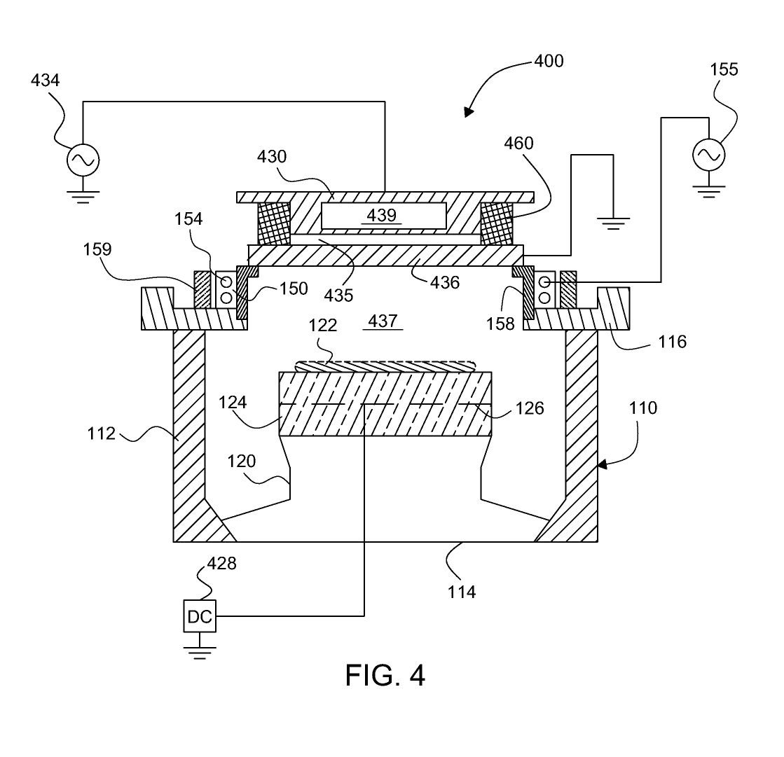

FIG. 4 is a cross sectional view of a chamber 400 according to another embodiment of the present invention. Chamber 400 includes a dual-channel showerhead 436 disposed below a showerhead 430 and above the substrate support 120. Chamber 400 further includes a dual-processing volume that is divided into a capacitive plasma processing zone and an inductive plasma processing zone 439. The capacitive processing zone includes a first volume within the chamber 400 and above the dual-channel showerhead 436, the first volume includes an interior volume 437 of showerhead 430 and a gap 435 between showerhead 430 and dual-channel showerhead 436. In some embodiments, the capacitive plasma zone could be limited to the gap 435. The inductive plasma processing zone 439 includes a second volume between the dual-channel showerhead 436 and the substrate support 120.

Showerhead 430 is mounted on top of showerhead insulator 460 to electrically isolate showerhead 430 from the chamber body 110 and from dual-channel showerhead 436. Showerhead 430 is spaced apart from dual-channel showerhead 436 to maintain a gap 435 between showerhead 430 and dual-channel showerhead 436.

Showerhead 430 could be electrically coupled to a capacitive RF power source 434. In some embodiments, capacitive RF power source 434 is coupled to a faceplate (not shown) of showerhead 430, and in some embodiments capacitive RF power source 434 is coupled to the top of the showerhead 430. In some embodiments only the showerhead faceplate is electrically conductive, and in other embodiments substantially all of the showerhead (e.g., showerhead 430) is electrically conductive. Dual-channel showerhead 436 could be formed of an electrically conductive material, and dual-channel showerhead 436 could be coupled to an electrical ground or other reference potential relative to showerhead 430. Application of RF power to showerhead 430 creates an oscillating electric field between showerhead 430 and the grounded dual-channel showerhead 436, ionizing process gases supplied to chamber 400 into a plasma. In some embodiments, the capacitive RF power source 434 may generate high frequency power, such as a frequency between 1 MHz and 100 MHz, such as 13.56 MHz or 60 MHz.

Dual-channel showerhead 436 may be mounted below showerhead insulator 460 and on top of coil insulator 158. Dual-channel showerhead 436 could have a design similar to dual-channel showerhead 330 (shown in FIG. 3A) with separate process gas inlet lines (e.g., 341, 342) to keep gases separate until the gases enter the inductive plasma processing zone 439. Gas from the capacitively coupled plasma zone could enter into one process gas inlet line, and a separate gas from an external source (not shown) could enter into another process gas inlet line of dual-channel showerhead 436. A tri-channel or other multi-channel showerhead could be used in place of dual-channel showerhead 436 to allow separate injection of additional process gases into the inductive plasma processing zone 439.

Once the process gases enter the inductive plasma processing zone 439, inductive RF power source 155 and coil 154 could be used to create an inductive plasma in a way similar to the inductive plasma created in chamber 100 described above. A DC biasing power source 428 could be coupled to the embedded electrode 126 of electrostatic chuck 124.

The embodiments discussed above provide examples of processing chambers that improve plasma uniformity. Plasma uniformity is improved by using a design with a capacitively coupled showerhead and an inductive coil surrounding the processing volume. Referring to FIG. 1, using showerhead faceplate 132 and electrode 126 to create a CCP is beneficial due to the location of showerhead faceplate 132 directly above substrate 122 and electrode 126 directly below substrate 122. Despite the benefits of creating a CCP this way, the plasma can still suffer from non-uniformities near the edge of the substrate 122. The problem of substrate edge non-uniformities in a CCP is solved here by creating or maintaining a plasma through the use of inductive coil 154. When inductive coils, such as coil 154, surround the processing volume, plasmas are created with a high degree of uniformity near the edges of the substrate. An ICP created or maintained this way may still suffer from plasma non-uniformities near the center of the substrate, but this problem is alleviated by the high degree of uniformity in the CCP at the center of the substrate. Furthermore, use of a showerhead, such as showerhead 130 or 436, to deliver the process gases from above substrate 122 ensures the process gases are distributed uniformly into the processing volume.

The embodiments discussed above also provide examples of processing chambers that can explore process conditions not possible with a stand-alone CCP chamber or a stand-alone ICP chamber. For example, chamber 100 could be used in a PECVD process, where the process conditions can be set between hundreds to thousands of Watts in a CCP mode and a few hundreds watts in ICP mode as well as a process pressure from hundreds of mTorr to hundreds of Torr.

The chambers discussed above can be operated in different plasma modes to allow for a full range of process conditions. For example, chamber 100 could be operated in CCP mode for one process, ICP mode for another process, and a hybrid CCP/ICP mode for yet another process. Referring to FIG. 4, chamber 400 having a dual-processing volume that is divided into a capacitive plasma processing zone and an inductive plasma processing zone allows for even more process conditions, that utilize a capacitive plasma flowing into an inductive power zone, to be explored. The embodiments described above also allows multiple semiconductor process steps, such as a deposition and cure, or a deposition and an etch, to be performed in the same chamber.

While the foregoing is directed to embodiments of the present invention, other and further embodiments of the invention may be devised without departing from the basic scope thereof, and the scope thereof is determined by the claims that follow.

1. A chamber for processing a substrate, comprising:
a chamber body having one or more sidewalls and a bottom;
a substrate support disposed inside the chamber body;
a showerhead disposed above the substrate support, the showerhead having a showerhead faceplate electrically coupled to a capacitive RF power source, wherein the showerhead faceplate faces the substrate support and a space between the substrate support and the showerhead faceplate defines a processing volume; and
one or more coils disposed outside the processing volume at a vertical location between the substrate support and the showerhead faceplate, wherein the one or more coils are electrically coupled to one or more inductive RF power sources.

2. The chamber of claim 1, further comprising a dual-channel showerhead disposed below the showerhead and above the substrate support and a dual-processing volume, wherein the dual-processing volume is divided into a capacitive plasma processing zone and an inductive plasma processing zone, the capacitive processing zone comprising a first volume within the chamber and above the dual-channel showerhead, and the inductive plasma processing zone comprising a second volume between the dual-channel showerhead and the substrate support.

3. The chamber of claim 1, wherein the substrate support comprises an electrostatic chuck having an embedded electrode electrically coupled to the capacitive RF power source and a DC biasing power source.

4. The chamber of claim 3, wherein the one or more coils comprises an upper coil disposed above a lower coil, the upper coil and the lower coil surrounding the processing volume.

5. The chamber of claim 4, wherein a position of the upper coil and the lower coil are each adjustable.

6. The chamber of claim 5, wherein the upper coil and the lower coil are electrically coupled to separate inductive RF power sources.

7. The chamber of claim 5, wherein the upper coil and the lower coil are electrically coupled to the same inductive RF power source.

8. The chamber of claim 6, further comprising at least one magnetic field concentrator disposed proximate to the upper coil and the lower coil.

9. The chamber of claim 3, wherein the one or more coils comprises a cylindrical coil forming two or more rings around the processing volume, each ring positioned at a different vertical location.

10. The chamber of claim 8, wherein the upper coil and the lower coil each comprise a cylindrical coil forming two or more rings around the processing volume, each ring having a different diameter.

11. A chamber for processing a substrate, comprising:
a chamber body having one or more sidewalls and a bottom,
a substrate support disposed inside the chamber body;
a showerhead disposed above the substrate support, the showerhead having a showerhead faceplate electrically coupled to a capacitive RF power source, wherein the showerhead faceplate faces the substrate support; and
one or more coils disposed outside of the chamber body at a vertical location between the substrate support and the showerhead faceplate, wherein the one or more coils are electrically coupled to one or more inductive RF power sources.

12. The chamber of claim 11, further comprising a dual-channel showerhead disposed below the showerhead and above the substrate support and a dual-processing volume, wherein the dual-processing volume is divided into a capacitive plasma processing zone and an inductive plasma processing zone, the capacitive processing zone comprising a first volume within the chamber and above the dual-channel showerhead, and the inductive plasma processing zone comprising a second volume between the dual-channel showerhead and the substrate support.

13. The chamber of claim 11, wherein the substrate support comprises an electrostatic chuck having an embedded electrode electrically coupled to the capacitive RF power source and a DC biasing power source.

14. The chamber of claim 13, wherein the one or more coils comprises an upper coil disposed above a lower coil, the upper coil and the lower coil surrounding the chamber body.

15. The chamber of claim 14, wherein a position of the upper coil and the lower coil are each adjustable.

16. The chamber of claim 15, wherein the upper coil and the lower coil are electrically coupled to separate inductive RF power sources.

17. The chamber of claim 15, wherein the upper coil and the lower coil are electrically coupled to the same inductive RF power source.

18. The chamber of claim 16, further comprising at least one magnetic field concentrator disposed proximate to the upper coil and the lower coil.

19. The chamber of claim 13, wherein the one or more coils comprises a cylindrical coil forming two or more rings around the chamber body, each ring positioned at a different vertical location.

20. The chamber of claim 18, wherein the upper coil and the lower coil each comprise a cylindrical coil forming two or more rings around the chamber body, each ring having a different diameter.
